(19) United States
(12) Patent Application Publication
(10) Pub. No.: US 2011/0065218 A1
(43) Pub. Date: Mar. 17, 2011

(54) PRE-THERMAL GREASED LED ARRAY

(75) Inventors: Robert Tudhope, Rancho Palos Verdes, CA (US); Alexander Rizkin, Redondo Beach, CA (US)

(73) Assignee: Bridgelux Inc., Sunnyvale, CA (US)

(21) Appl. No.: 12/646,596

(22) Filed: Dec. 23, 2009

Related U.S. Application Data
(60) Provisional application No. 61/242,221, filed on Sep. 14, 2009.

(51) Int. Cl. H01L 21/50

(52) U.S. Cl. 438/28; 257/E21.499

(57) ABSTRACT

An apparatus includes a backing material and a solid state component. The backing material carries a thermally conductive non-solid substance. The solid state component is set into the thermally conductive non-solid substance. The backing material is arranged with the solid state component so that the backing material may be removed from the apparatus leaving at least a portion of the thermally conductive non-solid substance on the solid state component for mounting to a heat sink.

### CROSS-REFERENCE TO RELATED APPLICATION(S)

Pursuant to 35 U.S.C. §119(e), this application claims the benefit of U.S. Provisional Application Ser. No. 61/242,221 filed on Sep. 14, 2009, the contents of which are hereby incorporated by reference herein in their entirety.

### BACKGROUND

1. Field

The present disclosure relates to a light emitting diode (LED) array module, and more particularly, to a pre-thermal greased LED array.

2. Description of Related Art

LEDs have been developed for many years and have been widely used in various light applications. As LEDs are light weight, consume less energy, and have a good electrical power to light conversion efficacy, they have been used to replace conventional light sources, such as incandescent lamps and fluorescent light sources. LEDs may be utilized in an array module. Heat is conducted from the LED array to a heat sink. The interface between the LED array and the heat sink may have gaps or voids. As such, a thermal interface material, such as thermal grease, may be used to fill the gaps and voids to aid in conducting heat from the LED array to the heat sink. Whether the thermal grease is applied by hand or by machine, the thermal grease may be misapplied, thus causing variation in thermal grease thickness and/or exposed areas where the thermal grease was not applied. Misapplication of the thermal grease to the LED array may shorten the lifespan of the LED array. As such, there is a need for a method for improving and an apparatus with improved thermal grease application.

### SUMMARY

In one aspect of the disclosure, an apparatus includes a backing material carrying a thermally conductive non-solid substance, and a solid state component set into the thermally conductive non-solid substance. The backing material is arranged with the solid state component so that the backing material may be removed from the apparatus leaving at least a portion of the thermally conductive non-solid substance on the solid state component for mounting to a heat sink.

In one aspect of the disclosure, an apparatus includes a backing material, a solid state component, and a thermally conductive non-solid substance between the backing material and the solid state component. The backing material is arranged with the solid state component so that the backing material may be removed from the apparatus leaving at least a portion of the thermally conductive non-solid substance on the solid state component for mounting to a heat sink.

In one aspect of the disclosure, an apparatus includes a solid state component and a backing material carrying a thermally conductive non-solid substance. The backing material is attached to the solid state component such that the thermally conductive non-solid substance is between the backing material and the solid state component. The backing material is arranged with the solid state component so that the backing material may be removed from the apparatus leaving at least a portion of the thermally conductive non-solid substance on the solid state component for mounting to a heat sink.

In one aspect of the disclosure, a method of producing a module from an apparatus having a backing material, a solid state component, and a thermally conductive non-solid substance between the backing material and the solid state component is provided. The method includes removing the backing material from the apparatus leaving at least a portion of the thermally conductive non-solid substance on the solid state component, and mounting the solid state component to a heat sink with the thermally conductive non-solid substance being between the solid state component and the heat sink.

In one aspect of the disclosure, a method of producing a plurality of apparatus includes applying a thermally conductive non-solid substance to a backing material, setting a solid state component into the thermally conductive non-solid substance in each of a plurality of backing material sections, and splitting the backing material into the sections to separate each of the backing sections.

In one aspect of the disclosure, an apparatus includes a frame, a solid state component secured to the frame, and a phase change thermal interface material coupled to the solid state component. The phase change thermal interface material is configured to be liquefied to fill voids adjacent the solid state component.

### BRIEF DESCRIPTION OF THE DRAWINGS

FIG. 1 is a conceptual cross-sectional side view illustrating an example of an LED.

FIG. 2 is a conceptual top view illustrating an example of a light emitting element.

FIG. 3A is a conceptual top view illustrating an example of a white light emitting element.

FIG. 3B is a conceptual cross-sectional side view of the white light emitting element in FIG. 3A.

FIG. 4 is a perspective view of a first LED array module.

FIG. 5 is an exploded view of the first LED array module.

FIG. 6 is a first perspective view of a second. LED array module.

FIG. 7 is a second perspective view of the second LED array module.

FIG. 8 is an exploded view of the second LED array module.

FIG. 9 is a view of a thermal grease sheet.

FIG. 10 shows a master slip sheet of a plurality of thermal grease sheets.

FIG. 11 is an illustration of a thermal grease sheet covering a layer of grease on a surface of an LED array.

### DETAILED DESCRIPTION

Various aspects of the present invention will be described herein with reference to drawings that are schematic illustrations of idealized configurations of the present invention. As such, variations from the shapes of the illustrations as a result, for example, manufacturing techniques and/or tolerances, are to be expected. Thus, the various aspects of the present invention presented throughout this disclosure should not be construed as limited to the particular shapes of elements (e.g., regions, layers, sections, substrates, etc.) illustrated and described herein but are to include deviations in shapes that result, for example, from manufacturing. By way of example, an element illustrated or described as a rectangle may have rounded or curved features and/or a gradient concentration at its edges rather than a discrete change from one element to another. Thus, the elements illustrated in the drawings are schematic in nature and their shapes are not intended to illustrate the precise shape of an element and are not intended to limit the scope of the present invention.

It will be understood that when an element such as a region, layer, section, substrate, or the like, is referred to as being “on” another element, it can be directly on the other element or intervening elements may also be present. In contrast, when an element is referred to as being “directly on” another element, there are no intervening elements present. It will be further understood that when an element is referred to as being “formed” on another element, it can be grown, deposited, etched, attached, connected, coupled, or otherwise prepared or fabricated on the other element or an intervening element. In addition, when a first element is “coupled” to a second element, the first element may be directly connected to the second element or the first element may be indirectly connected to the second element with intervening elements between the first and second elements.

Furthermore, relative terms, such as “lower” or “bottom” and “upper” or “top,” may be used herein to describe one element's relationship to another element as illustrated in the drawings. It will be understood that relative terms are intended to encompass different orientations of an apparatus in addition to the orientation depicted in the drawings. By way of example, if an apparatus in the drawings is turned over, elements described as being on the “lower” side of other elements would then be oriented on the “upper” side of the other elements. The term “lower” can therefore encompass both an orientation of “lower” and “upper,” depending of the particular orientation of the apparatus. Similarly, if an apparatus in the drawing is turned over, elements described as “below” or “beneath” other elements would then be oriented “above” the other elements. The terms “below” or “beneath” can therefore encompass both an orientation of above and below.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and this disclosure.

As used herein, the singular forms “a,” “an,” and “the” are intended to include the plural forms as well, unless the context clearly indicates otherwise. It will be further understood that the terms “comprise,” “comprises,” and/or “comprising,” when used in this specification, specify the presence of stated features, integers, steps, operations, elements, and/or components, but do not preclude the presence or addition of one or more other features, integers, steps, operations, elements, components, and/or groups thereof. The term “and/or” includes any and all combinations of one or more of the associated listed items.

Various aspects of an LED array module may be illustrated with reference to one or more exemplary configurations. As used herein, the term “exemplary” means “serving as an example, instance, or illustration,” and should not necessarily be construed as preferred or advantageous over other configurations of an LED array module disclosed herein.

Furthermore, various descriptive terms used herein, such as “on” and “transparent,” should be given the broadest meaning possible within the context of the present disclosure. For example, when a layer is said to be “on” another layer, it should be understood that that one layer may be deposited, etched, attached, or otherwise prepared or fabricated directly or indirectly above or below that other layer. In addition, something that is described as being “transparent” should be understood as having a property allowing no significant obstruction or absorption of electromagnetic radiation in the particular wavelength (or wavelengths) of interest, unless a particular transmittance is provided.

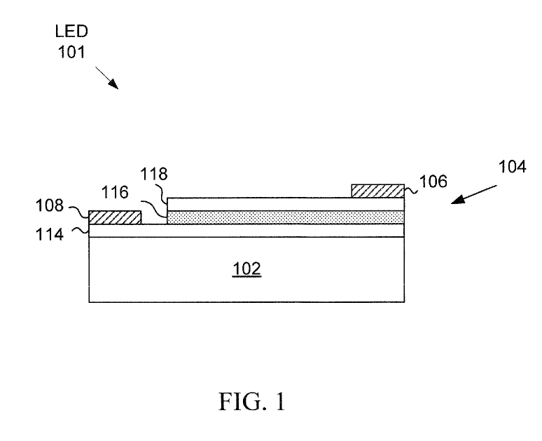

An example of a solid state light emitting cell is an LED. The LED is well known in the art, and therefore, will only briefly be discussed to provide a complete description of the invention. FIG. 1 is a conceptual cross-sectional side view illustrating an example of an LED. An LED is a semiconductor material impregnated, or doped, with impurities. These impurities add “electrons” and “holes” to the semiconductor, which can move in the material relatively freely. Depending on the kind of impurity, a doped region of the semiconductor can have predominantly electrons or holes, which is referred to as n-type or a p-type semiconductor region, respectively. In LED applications, the semiconductor includes an n-type semiconductor region, a p-type semiconductor region, and an intervening active region between the n-type and p-type semiconductor regions. When a forward voltage sufficient to overcome the reverse electric field is applied across the p-n junction, electrons and holes are forced into the active region and combine. When electrons combine with holes, they fall to lower energy levels and release energy in the form of light.

Referring to FIG. 1, the LED 101 includes a substrate 102, an epitaxial-layer structure 104 on the substrate 102, and a pair of electrodes 106 and 108 on the epitaxial-layer structure 104. The epitaxial-layer structure 104 comprises an active region 116 sandwiched between two oppositely doped epitaxial regions. In this example, an n-type semiconductor region 114 is formed on the substrate 102 and a p-type semiconductor region 118 is formed on the active region 116, however, the regions may be reversed. That is, the p-type semiconductor region 118 may be formed on the substrate 102 and the n-type semiconductor region 114 may formed on the active region 116. As those skilled in the art will readily appreciate, the various concepts described throughout this disclosure may be extended to any suitable epitaxial-layer structure. Additional layers (not shown) may also be included in the epitaxial-layer structure 104, including but not limited to buffer, nucleation, contact and current spreading layers as well as light extraction layers.

The electrodes 106 and 108 may be formed on the surface of the epitaxial-layer structure 104. The p-type semiconductor region 118 is exposed at the top surface, and therefore, the p-type electrode 106 may be readily formed thereon. However, the n-type semiconductor region 114 is buried beneath the p-type semiconductor region 118 and the active region 116. Accordingly, to form the n-type electrode 108 on the n-type semiconductor region 114, a portion of the active region 116 and the p-type semiconductor region 118 is removed to expose the n-type semiconductor region 114 therebeneath. After this portion of the epitaxial-layer structure 104 is removed, the n-type electrode 108 may be formed.

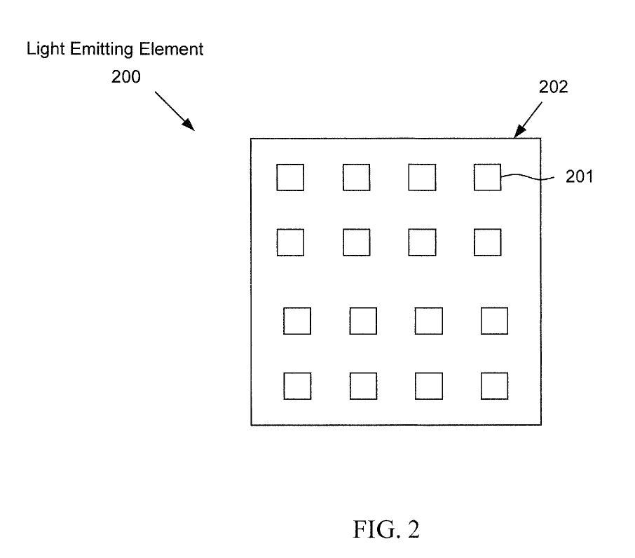

As discussed above, one or more light emitting cells may be used to construct a light emitting element. A light emitting element may be constructed in a 2-dimensional planar fashion. One example of a light emitting element will now be presented with reference to FIG. 2. FIG. 2 is a conceptual top view illustrating an example of a light emitting element. In this example, a light emitting element 200 is configured with multiple LEDs 201 arranged on a substrate 202. The substrate 202 may be made from any suitable material that provides mechanical support to the LEDs 201. Preferably, the material is thermally conductive to dissipate heat away from the LEDs 201. The substrate 202 may include a dielectric layer (not shown) to provide electrical insulation between the LEDs 201. The LEDs 201 may be electrically coupled in parallel and/or series by a conductive circuit layer, wire bonding, or a combination of these or other methods on the dielectric layer.

The light emitting element may be configured to produce white light. White light may enable the light emitting element to act as a direct replacement for conventional light sources used today in incandescent, halogen and fluorescent lamps. There are at least two common ways of producing white light. One way is to use individual LEDs that emit wavelengths (such as red, green, blue, amber, or other colors) and then mix all the colors to produce white light. The other way is to use a phosphor material or materials to convert monochromatic light emitted from a blue or ultra-violet (UV) LED to broad-spectrum white light. The present invention, however, may be practiced with other LED and phosphor combinations to produce different color lights.

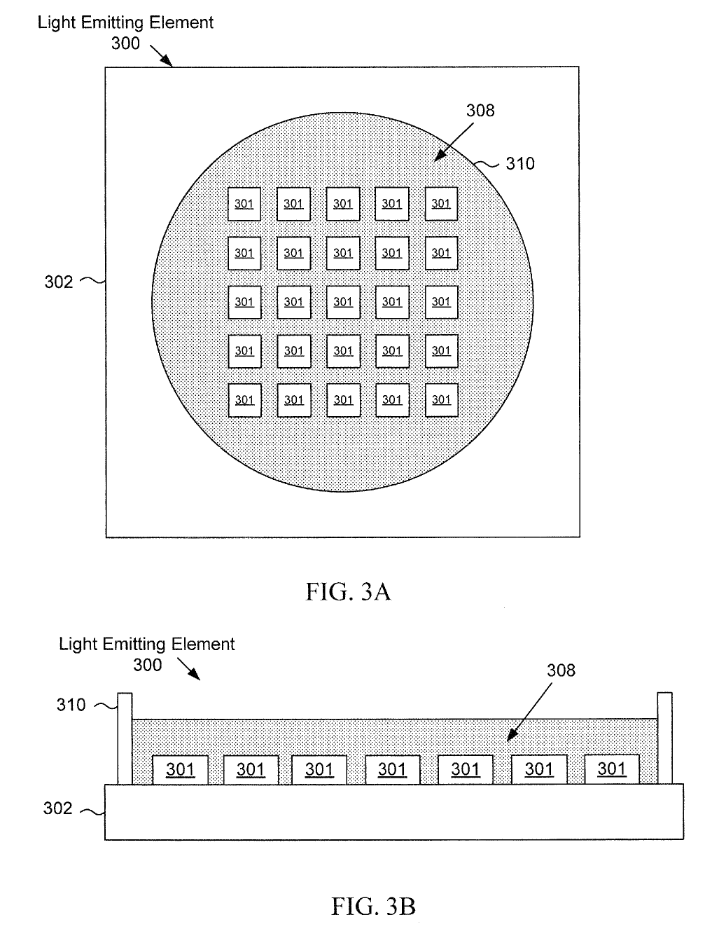

An example of a white light emitting element will now be presented with reference to FIGS. 3A and 3B. FIG. 3A is a conceptual top view illustrating an example of a white light emitting element and FIG. 3B is a conceptual cross-sectional side view of the white light emitting element in FIG. 3A. The white light emitting element 300 is shown with a substrate 302 which may be used to support multiple LEDs 301. The substrate 302 may be configured in a manner similar to that described in connection with FIG. 2 or in some other suitable way. A phosphor material 308 may be deposited within a cavity defined by an annular, or other shaped, or other boundary 310 that extends circumferentially, or in any shape, around the upper surface of the substrate 302. The annular boundary 310 may be formed with a suitable mold, or alternatively, formed separately from the substrate 302 and attached to the substrate 302 using an adhesive or other suitable means. The phosphor material 308 may include, by way of example, phosphor particles suspended in an epoxy, silicone, or other carrier or may be constructed from a soluble phosphor that is dissolved in the carrier.

In an alternative configuration of a white light emitting element, each LED may have its own phosphor layer. As those skilled in the art will readily appreciate, various configurations of LEDs and other light emitting cells may be used to create a white light emitting element. Moreover, as noted earlier, the present invention is not limited to solid state lighting devices that produce white light, but may be extended to solid state lighting devices that produce other colors of light.

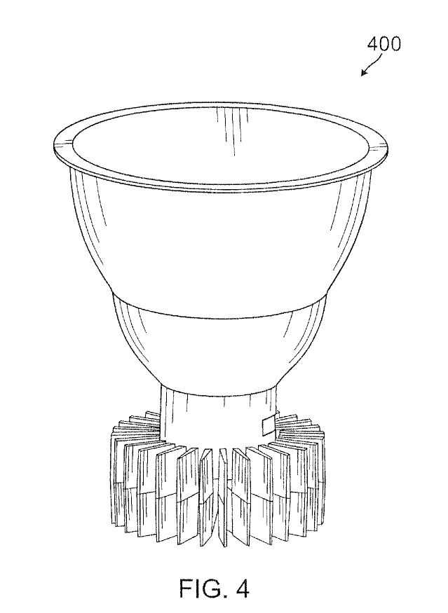

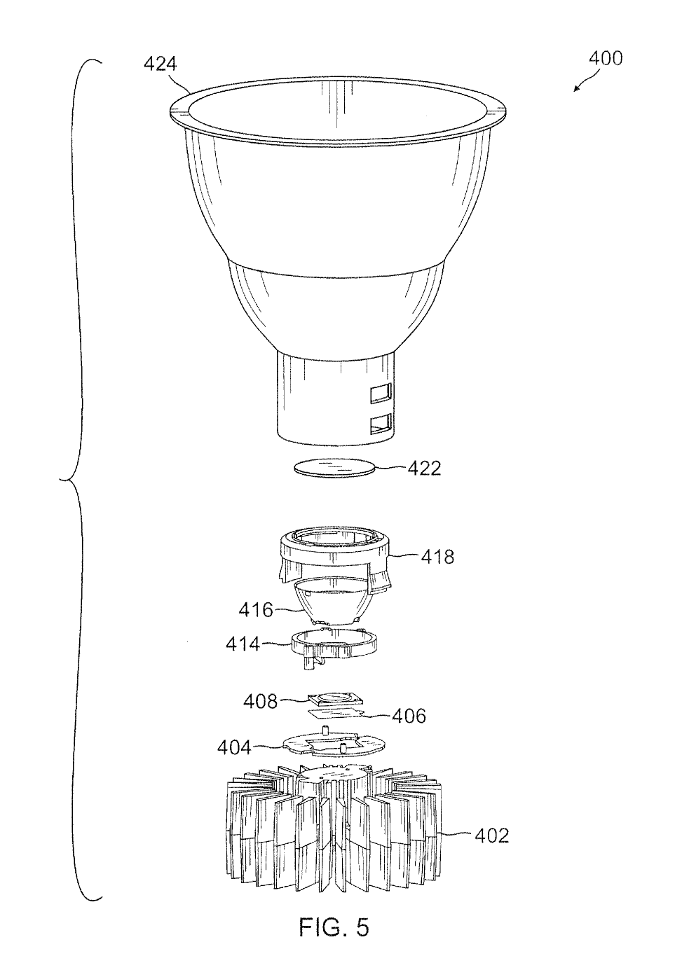

FIG. 4 is a perspective view of a first LED array module 400. FIG. 5 is an exploded view of the first LED array module 400. As shown in FIG. 4 and FIG. 5, the LED array module 400 includes a heat sink 402. A printed circuit board 404 may attach to frame 414. The frame 414 may attach to the heat sink 402. The LED array 408, which may be the light emitting element 200 or the light emitting element 300, is attachable to the frame 414. The LED array 408 may have a metalized bottom surface for conducting heat away from the substrate of the LED array 408. The LED array 408 may have a thermal grease sheet 406 that can be removed prior to positioning the LED array 408 against the heat sink 402. The primary optical element, the reflector 416, inserts within the frame 414 and attaches to the LED array 408. The secondary optical element, the lens/diffuser 422, may cover the reflector 416. The cover 418 attaches to the frame 414 in order to provide a supporting structure for securing the LED components 402-422 to the reflector 424.

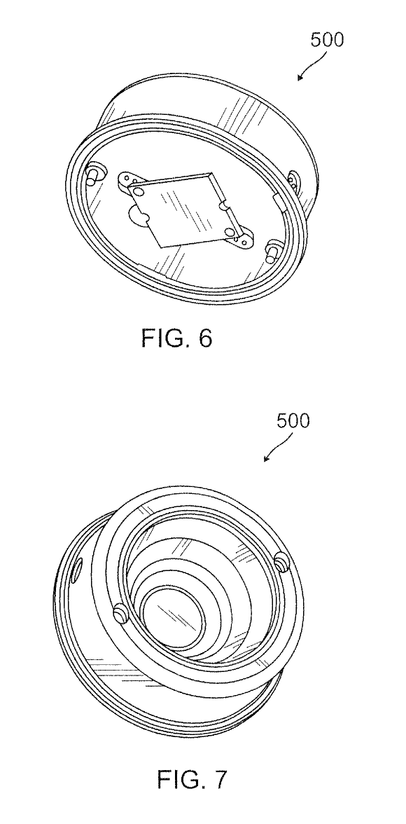

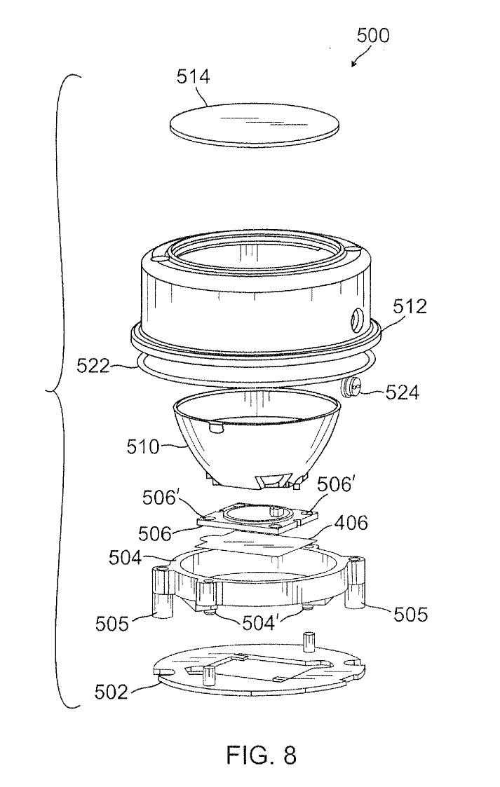

FIG. 6 is a first perspective view of a second LED array module 500. FIG. 7 is a second perspective view of the second LED array module 500. FIG. 8 is an exploded view of the second LED array module 500. The LED array module 500 includes a printed circuit board 502 attachable to the frame 504, a frame 504 attachable to the heat sink, an LED array 506 attachable to the frame 504, a removable thermal grease sheet 406 that is attached to a bottom surface of the LED array 506 and is removed prior to attaching the module 500 to a heat sink, a reflector 510 for transforming light from the LED array 506, a cover 512 for covering the LED array 506 and the reflector 510, and a secondary optic 514 for further transforming the light emitted from the LED array 506. The LED array 506 may be the light emitting element 200 or the light emitting element 300. The LED array 506 is sealed within the cover 512 with the silicone o-ring 522 and the rubber grommet 524 that is insertable into a hole in the side of the cover 512.

The frame 504 has torsion pins 504′ for attaching to the corresponding holes 506′ in the LED array 506. The torsion pins 504′ extend slightly below the legs 505 of the frame 504. Such a configuration of the legs 505 and torsion pins 504′ allow for a constant pressure to be applied against the LED array 506 when the frame 504 is attached to a heat sink. In one configuration, the thermal grease sheet 406 is a phase change thermal interface material. Phase change thermal interface pads melt and liquefy when heated. The liquefied thermal interface material fills micro voids, thus providing better contact between the heat sink and the metalized bottom surface of the LED array 506. The pressure applied by the frame 504 on the LED array 506 takes up any voids left by the displaced liquefied thermal interface material. As such, after the phase change thermal interface pads are melted, the metalized bottom surface of the LED array 506 maintains a good thermal metal-to-metal contact with the heat sink through the liquefied thermal interface material.

The thermal grease sheet 406 may be plastic, wax paper, or another suitable material for covering a layer of thermal grease on the bottom surface of the LED array 408, 506. When the LED array 408 is attached to the heat sink 402 or when the module 500 is mounted to a heat sink, the thermal grease sheet 406 is removed, revealing the layer of grease. The layer of grease conducts heat from the LED array 408, 506 to the heat sink.

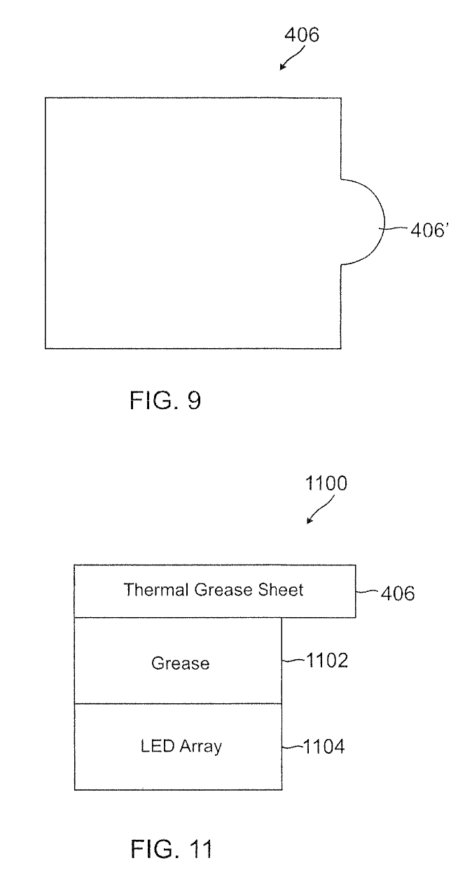

FIG. 9 is a view of the thermal grease sheet 406. As discussed supra, the thermal grease sheet 406 may be plastic, wax paper, silicone, or another suitable material for protecting a layer of grease on the substrate (bottom surface) of the LED array 408, 506 before the LED array 408, 506 is mounted to a heat sink. The thermal grease sheet 406 may include a tab 406′ for allowing the grease sheet 406 to be gripped and removed from the layer of grease once the layer of grease is attached to the substrate of the LED array 408, 506. The thermal grease sheet 406 may be referred to as a backing material and the thermal grease may be referred to as a thermally conductive non-solid substance. The thermal grease may also be referred to as a thermal compound, a thermal paste, a thermal lubricant, heat paste, heat sink paste, heat transfer compound, phase change thermal interface material, or heat sink compound. The thermal grease may be silicone grease medium with small, thermally conductive particles. The particles may be ceramic, metal, carbon, or a liquid metal alloy such as gallium.

FIG. 10 shows a master slip sheet 1000 of a plurality of thermal grease sheets 406. The master slip sheet 1000 may be prescored along prescore lines 1002. Subsequently, a layer of grease is applied evenly on top of the master slip sheet 1000. The layer of grease may be applied to the master slip sheet 1000 through a silk screening process using a squeegee or a roller to control the even application of the grease to the master slip sheet 1000. Once the grease is evenly applied to the master slip sheet 1000, the individual thermal grease sheets 406 may be separated individually along the prescore lines 1002 and applied to an LED array. Alternatively, an LED array may be placed onto the grease layer of each individual thermal grease sheet 406, providing pre-thermal greased LED array components that can later be attached to the corresponding frame 414, 504. After a thermal grease sheet 406 and an LED array are attached, the thermal grease sheet 406 protects the intervening layer of thermal grease, maintains the even distribution of the layer of grease on the surface of the LED array, and prevents dust or other particles from sticking to the grease layer. Once the LED array is ready for installation for attachment to a heat sink, the thermal grease sheet 406 is removed from the grease layer to expose the grease layer, and the greasy surface of the LED array is attached to an associated heat sink.

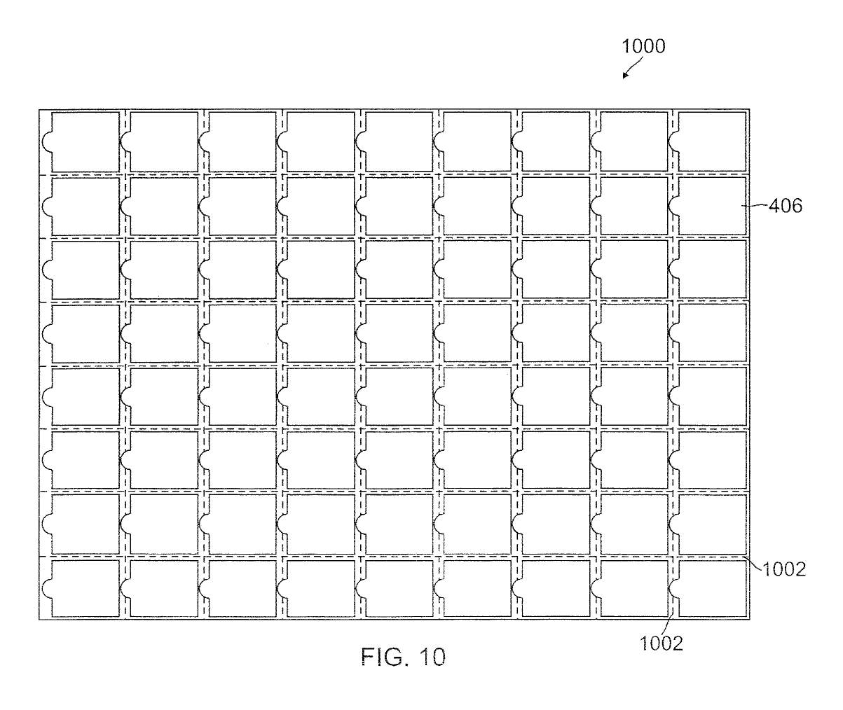

FIG. 11 is an illustration 1100 of a thermal grease sheet 406 covering a layer of grease 1102 on a bottom surface of an LED array 1104, which may be the LED array 408 or the LED array 506. As discussed supra, a grease layer 1102 may be applied to a master slip sheet. Subsequently, sectioned LED arrays may be attached to the grease layer 1102 and the thermal grease sheets 406 may be separated, thus providing a pre-thermal greased LED array 1100. The thermal grease sheet 406 protects the layer of grease 1102 by maintaining the even distribution of the layer of grease 1102 on the LED array 1104 and by preventing dust or other particles from sticking to the grease. When the LED array 1100 is ready to be mounted to a heat sink, the thermal grease sheet 406 is removed from the grease layer 1102, as discussed supra.

As discussed supra, the LED array modules 400, 500 include an LED array. However, the modules 400, 500 may alternatively include a solid state component, the solid state component being a device built entirely from solid materials in which the electrons are entirely confined within the solid material. The solid state component may be a light source. The light source may be constructed from an array of light emitting semiconductor cells. One example of a light emitting semiconductor cell is an LED.

The various aspects of this disclosure are provided to enable one of ordinary skill in the art to practice the present invention. Modifications to various aspects of an LED array module presented throughout this disclosure will be readily apparent to those skilled in the art, and the concepts disclosed herein may be extended to other applications. Thus, the claims are not intended to be limited to the various aspects of an LED array module presented throughout this disclosure, but are to be accorded the full scope consistent with the language of the claims. All structural and functional equivalents to the elements of the various aspects described throughout this disclosure that are known or later come to be known to those of ordinary skill in the art are expressly incorporated herein by reference and are intended to be encompassed by the claims. Moreover, nothing disclosed herein is intended to be dedicated to the public regardless of whether such disclosure is explicitly recited in the claims. No claim element is to be construed under the provisions of 35 U.S.C. §112, sixth paragraph, unless the element is expressly recited using the phrase “means for” or, in the case of a method claim, the element is recited using the phrase “step for.”

What is claimed is:

1. An apparatus, comprising:
a backing material carrying a thermally conductive non-solid substance; and
a solid state component set into the thermally conductive non-solid substance;
wherein the backing material is arranged with the solid state component so that the backing material may be removed from the apparatus leaving at least a portion of the thermally conductive non-solid substance on the solid state component for mounting to a heat sink.

2. The apparatus of claim 1, wherein the solid state component comprises a light source.

3. The apparatus of claim 2, wherein the light source comprises a white light source.

4. The apparatus of claim 2, wherein the light source comprises an array of light emitting semiconductor cells.

5. The apparatus of claim 4, wherein the light source further comprises a substrate carrying the array of light emitting semiconductor cells.

6. The apparatus of claim 4, further comprising phosphor arranged with the array of light emitting semiconductor cells such that the light source produces white light.

7. The apparatus of claim 1, wherein the backing material comprises a slip sheet.

8. The apparatus of claim 1, wherein the backing material comprises wax paper.

9. The apparatus of claim 1, wherein the backing material comprises plastic.

10. The apparatus of claim 1, wherein the backing material comprises a tab to facilitate the removal of the backing material from the solid state component.

11. The apparatus of claim 1, wherein the thermally conductive non-solid substance comprises thermal grease.

12. The apparatus of claim 1, wherein the thermally conductive non-solid substance comprises a silicone grease medium with particles suspended in the silicone grease medium.

13. An apparatus, comprising:
a backing material;
a solid state component; and
a thermally conductive non-solid substance between the backing material and the solid state component;
wherein the backing material is arranged with the solid state component so that the backing material may be removed from the apparatus leaving at least a portion of the thermally conductive non-solid substance on the solid state component for mounting to a heat sink.

14. The apparatus of claim 13, wherein the solid state component comprises a light source.

15. The apparatus of claim 14, wherein the light source comprises a white light source.

16. The apparatus of claim 14, wherein the light source comprises an array of light emitting semiconductor cells.

17. The apparatus of claim 16, wherein the light source further comprises a substrate carrying the array of light emitting semiconductor cells.

18. The apparatus of claim 16, further comprising phosphor arranged with the array of light emitting semiconductor cells such that the light source produces white light.

19. The apparatus of claim 13, wherein the backing material comprises a slip sheet.

20. The apparatus of claim 13, wherein the backing material comprises wax paper.

21. The apparatus of claim 13, wherein the backing material comprises plastic.

22. The apparatus of claim 13, wherein the backing material comprises a tab to facilitate the removal of the backing material from the apparatus.

23. The apparatus of claim 13, wherein the thermally conductive non-solid substance comprises thermal grease.

24. The apparatus of claim 13, wherein the thermally conductive non-solid substance comprises a silicone grease medium with particles suspended in the silicone grease medium.

25. An apparatus, comprising:
a solid state component; and
a backing material carrying a thermally conductive non-solid substance, the backing material being attached to the solid state component such that the thermally conductive non-solid substance is between the backing material and the solid state component;
wherein the backing material is arranged with the solid state component so that the backing material may be removed from the apparatus leaving at least a portion of the thermally conductive non-solid substance on the solid state component for mounting to a heat sink.

26. The apparatus of claim 25, wherein the solid state component comprises a light source.

27. The apparatus of claim 26, wherein the light source comprises a white light source.

28. The apparatus of claim 26, wherein the light source comprises an array of light emitting semiconductor cells.

29. The apparatus of claim 28, wherein the light source further comprises a substrate carrying the array of light emitting semiconductor cells.

30. The apparatus of claim 28, further comprising phosphor arranged with the array of light emitting semiconductor cells such that the light source produces white light.

31. The apparatus of claim 25, wherein the backing material comprises a slip sheet.

32. The apparatus of claim 25, wherein the backing material comprises wax paper.

33. The apparatus of claim 25, wherein the backing material comprises plastic.

34. The apparatus of claim 25, wherein the backing material comprises a tab to facilitate the removal of the backing material from the solid state component.

35. The apparatus of claim 25, wherein the thermally conductive non-solid substance comprises thermal grease.

36. The apparatus of claim 25, wherein the thermally conductive non-solid substance comprises a silicone grease medium with particles suspended in the silicone grease medium.

37. A method of producing a module from an apparatus having a backing material, a solid state component, and a thermally conductive non-solid substance between the backing material and the solid state component, the method comprising:
removing the backing material from the apparatus leaving at least a portion of the thermally conductive non-solid substance on the solid state component; and
mounting the solid state component to a heat sink with the thermally conductive non-solid substance being between the solid state component and the heat sink.

38. The method of claim 37, wherein the solid state component comprises a light source.

39. The method of claim 38, further comprising arranging at least one reflector with the light source.

40. The method of claim 38, further comprising arranging a lens with the light source.

41. The method of claim 38, further comprising attaching the light source, at least one reflector, and a lens to a frame.

42. The method of claim 41, further comprising attaching a printed circuit board to the frame.

43. The method of claim 38, further comprising coupling the light source, at least one reflector, and a lens together with a cover.

44. The method of claim 38, wherein the light source comprises a white light source.

45. The method of claim 38, wherein the light source comprises an array of light emitting semiconductor cells.

46. The method of claim 45, wherein the light source further comprises a substrate carrying the array of light emitting semiconductor cells.

47. The method of claim 45, wherein the apparatus further comprises phosphor arranged with the array of light emitting semiconductor cells such that the light source produces white light.

48. The method of claim 37, wherein the backing material comprises a slip sheet.

49. The method of claim 37, wherein the backing material comprises wax paper.

50. The method of claim 37, wherein the backing material comprises plastic.

51. The method of claim 37, wherein the backing material comprises a tab, the tab being used to remove the backing material from the apparatus.

52. The method of claim 37, wherein the thermally conductive non-solid substance comprises thermal grease.

53. The method of claim 37, wherein the thermally conductive non-solid substance comprises a silicone grease medium with particles suspended in the silicone grease medium.

54. A method of producing a plurality of apparatus, comprising:
applying a thermally conductive non-solid substance to a backing material;
setting a solid state component into the thermally conductive non-solid substance in each of a plurality of backing material sections; and
splitting the backing material into the backing material sections to separate each of the backing material sections.

55. The method of claim 54, further comprising pre-scoring backing material into the backing material sections.

56. The method of claim 54, wherein the thermally conductive non-solid substance is applied to the backing material with a squeegee or a roller.

57. The method of claim 54, wherein the backing material is split before the solid state components are attached to the backing material sections.

58. The method of claim 54, wherein the backing material is split after the solid state components are attached to the backing material sections.

59. An apparatus, comprising:
a frame;
a solid state component secured to the frame; and
a phase change thermal interface material coupled to the solid state component,
wherein the phase change thermal interface material is configured to be liquefied to fill voids adjacent the solid state component.

60. The apparatus of claim 59, wherein the phase change thermal interface material is a phase change thermal interface pad.

61. The apparatus of claim 59, further comprising a heat sink attached to the frame such that the phase change thermal interface material is between the solid state component and the heat sink, wherein the phase change thermal interface material is configured to be liquefied to fill voids between the solid state component and the heat sink.

62. The apparatus of claim 59, wherein the frame is configured to apply pressure against the phase change thermal interface material.

63. The apparatus of claim 59, wherein the solid state component comprises a light source.

64. The apparatus of claim 63, wherein the light source comprises a white light source.

65. The apparatus of claim 63, wherein the light source comprises an array of light emitting semiconductor cells.

66. The apparatus of claim 65, wherein the light source further comprises a substrate carrying the array of light emitting semiconductor cells.

67. The apparatus of claim 65, further comprising phosphor arranged with the array of light emitting semiconductor cells such that the light source produces white light.
